(19) United States
(12) Patent Application Publication
(10) Pub. No.: US 2020/0196482 A1
(43) Pub. Date: Jun. 18, 2020

(54) HEAT DISSIPATION UNIT

(71) Applicant: ASIA VITAL COMPONENTS CO., LTD., New Taipei City (TW)

(72) Inventors: Kuei-Feng Chiang, New Taipei City (TW); Kuo-Chun Hsieh, New Taipei City (TW)

(21) Appl. No.: 16/221,591

(22) Filed: Dec. 17, 2018

(51) Int. Cl. H05K 7/20

(52) U.S. Cl. CPC H05K 7/20154; H05K 7/2039

(57) ABSTRACT

A heat dissipation unit includes a main body having an upper surface and a lower surface and at least one heat conduction member having a heat absorption face and a heat conduction face. The heat conduction face of the heat conduction member is disposed under the lower surface of the main body.

### BACKGROUND OF THE INVENTION

### 1. Field of the Invention

The present invention relates generally to a heat dissipation unit, and more particularly to a heat dissipation unit including a main body and at least one heat conduction member connected on an outer surface of the main body. The heat conduction member serves to contact a heat generation component the height of which is lower than the heights of the adjacent electronic components so as to dissipate the heat of the heat generation component and achieve better heat dissipation effect.

### 2. Description of the Related Art

It is known that the operation performances of the current mobile devices, personal computers, servers, communication chassis and other systems or devices have become higher and higher. As a result, the heat generated by the internal heat generation components (such as, but not limited to chips) of these electronic devices has become higher and higher. Moreover, the current electronic equipments have more and more diversified functions and various heat generation components are arranged on the circuit boards of the current electronic equipments. A vapor chamber is used to face-to-face conduct heat by larger area. The vapor chamber is a rectangular or nonrectangular case (or plate body). A capillary structure is disposed on at least one inner wall face of the internal chamber of the case.

In addition, a working fluid is filled in the chamber of the case. One face (heated face) of the case is attached to the heat generation component to absorb the heat generated by the heat generation component, whereby the liquid working fluid is evaporated into vapor working fluid and the heat is conducted to the other face (condensation face) of the case. The vapor working fluid is cooled and condensed into liquid working fluid. The liquid working fluid further flows back to the heated face due to gravity or capillary attraction of the capillary structure to continue the vapor-liquid circulation. Accordingly, the heat can be spread and dissipated. The vapor chamber has a larger contact area for conducting the heat. This is different from the heat pipe, which is used to point-to-point conduct heat. Therefore, the vapor chamber is applicable to a heat generation component with larger heat generation area or multiple heat generation components with shorter distance.

However, according to the design of the electronic circuit of the current circuit board, the height of the heat generation component the heat of which needs to be dissipated may be lower than that of the peripheral or adjacent electronic components such as a resistor, a capacitor or a passive component. Therefore, it is hard for the conventional heat dissipation component such as a heat sink, a heat pipe, a vapor chamber or a loop-type heat pipe to fully snugly attach to the heat generation component.

The conventional heat dissipation component has another problem. That is, in case that there are multiple heat generation components the heat of which needs to be dissipated, the heights of these heat generation components are often unequal to each other. Conventionally, when a vapor chamber is applied to a lower heat generation component with or multiple heat generation components with different heights, it is necessary to bend (sink) the vapor chamber so that the vapor chamber can be snugly attached to the heat generation components with different heights. However, after the vapor chamber is bent (sunken), the capillary structure in the chamber is apt to be damaged (such as detached from the inner wall face) to block the vapor passage or the capillary structure may fail due to over-bending. In this case, the liquid working fluid will be unable to flow back to the heated face. As a result, the heat dissipation effect of the entire vapor chamber will be deteriorated or even lost to cause overheating of the heat generation component.

It is therefore tried by the applicant to provide a heat dissipation unit to solve the above problems existing in the conventional heat dissipation component.

### SUMMARY OF THE INVENTION

It is therefore a primary object of the present invention to provide a heat dissipation unit including a main body and at least one heat conduction member connected on an outer surface of the main body. The heat dissipation unit is able to snugly attach to a heat generation component the height of which is lower than the heights of the peripheral or adjacent electronic components or multiple heat generation components with different heights so as to effectively dissipate the heat of the heat generation component and achieve better heat dissipation effect.

To achieve the above and other objects, the heat dissipation unit of the present invention includes a main body having an upper surface and a lower surface and at least one heat conduction member having a heat absorption face and a heat conduction face. The heat conduction face of the heat conduction member is disposed under the lower surface of the main body.

According to the design of the present invention, the at least one heat conduction member of the heat dissipation unit is able to directly attach to a heat generation component the height of which is lower than the heights of the peripheral or adjacent electronic components or multiple heat generation components with different heights without bending (sinking) the heat dissipation unit. Therefore, the capillary structure in the chamber of the heat dissipation unit will not be damaged to block the vapor passage. In this case, a better heat dissipation effect can be achieved.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view of a first embodiment of the heat dissipation unit of the present invention;

FIG. 2 is a perspective exploded view of the first embodiment of the heat dissipation unit of the present invention, seen from another angle;

FIG. 3 is a sectional assembled view of the first embodiment of the heat dissipation unit of the present invention;

FIG. 4 is a sectional assembled view of the first embodiment of the heat dissipation unit of the present invention, showing that a connection medium layer is formed under the lower surface of the main body of the heat dissipation unit;

FIG. 5 is a perspective exploded view of a second embodiment of the heat dissipation unit of the present invention;

FIG. 6 is a perspective exploded view of the second embodiment of the heat dissipation unit of the present invention, seen from another angle;

FIG. 7 is a sectional assembled view of the second embodiment of the heat dissipation unit of the present invention; and

FIG. 8 is a sectional assembled view of the second embodiment of the heat dissipation unit of the present invention, showing that two connection medium layers are formed under the lower surface of the main body of the heat dissipation unit.

### DETAILED DESCRIPTION OF THE PREFERRED EMBODIMENTS

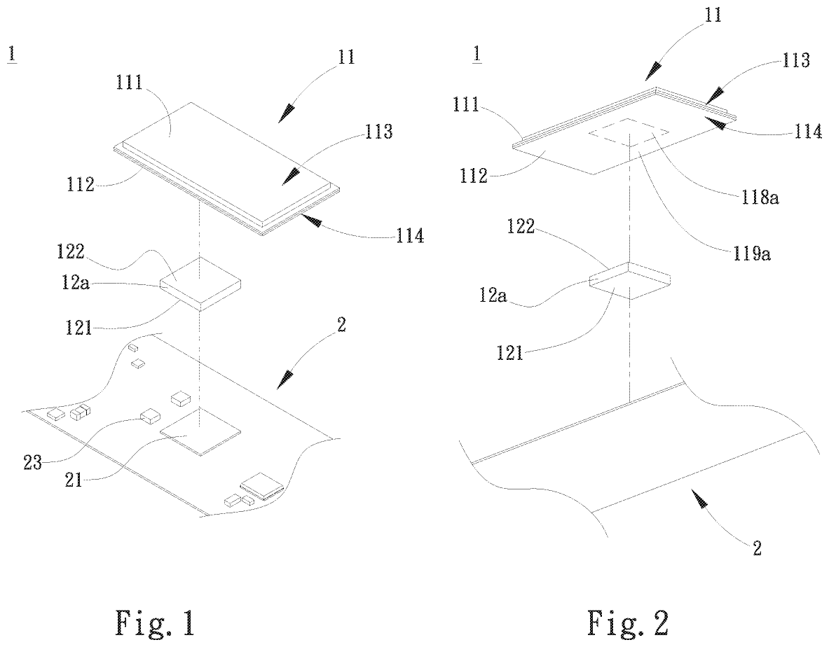

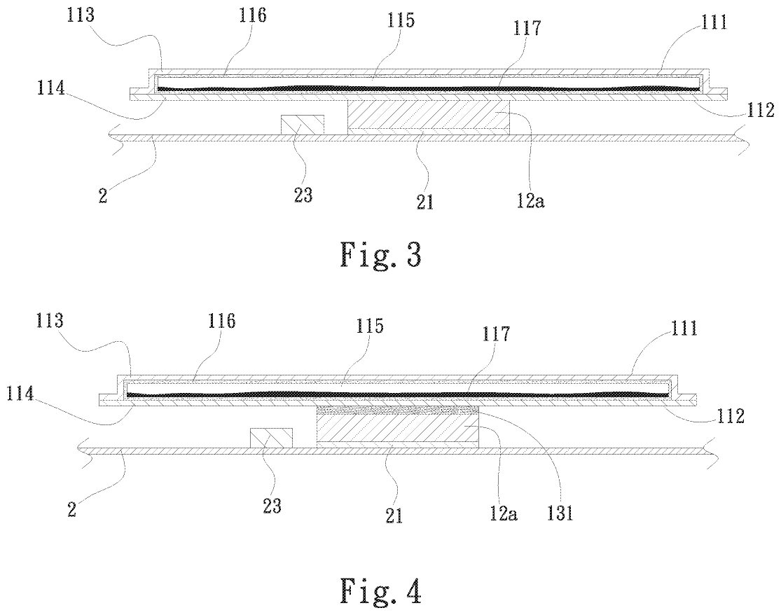

Please refer to FIGS. 1, 2 and 3. FIG. 1 is a perspective exploded view of a first embodiment of the heat dissipation unit of the present invention. FIG. 2 is a perspective exploded view of the first embodiment of the heat dissipation unit of the present invention, seen from another angle. FIG. 3 is a sectional assembled view of the first embodiment of the heat dissipation unit of the present invention. According to the first embodiment, the heat dissipation unit 1 of the present invention is applied to a heat source of an electronic device, the heat of which needs to be dissipated. In this embodiment, the heat dissipation unit 1 is in contact with and attached to at least one heat generation component 21 disposed on a circuit board 2 (such as a motherboard) of the electronic device to dissipate the heat of the heat generation component 21. In this embodiment, the height of the heat generation component 21 is lower than that of the peripheral electronic components 23, (such as a central processing unit or a graphics processing unit). The heat generation component 21 is not limited to the central processing unit and the graphics processing unit. In practice, the heat generation component 21 can be alternatively a Northbridge/Southbridge chipset or a transistor or any other electronic component arranged on the circuit board, the heat of which needs to be dissipated.

The heat dissipation unit 1 includes a main body 11 and at least one heat conduction member 12a. In this embodiment, the main body 11 is a vapor chamber. In a modified embodiment, the main body 11 can be alternatively a heat conduction base body (such as a metal block or alloy block with high thermal conductivity), a heat sink (such as extruded aluminum heat sink or fin-type heat sink), a heat pipe, a loop-type heat pipe or a combination thereof. In this embodiment, the at least one heat conduction member 12a is a solid heat conduction block. In a modified embodiment, the at least one heat conduction member 12a can be alternatively a hollow heat conduction body with a chamber (such as a vapor chamber or a flat-plate heat pipe). In this embodiment, the at least one heat conduction member is one heat conduction member 12a corresponding to one heat generation component 21. The number of the heat conduction member and the number of the heat generation component are not limited to one. Some modifications can be made. This will be specifically described hereinafter. The heights of the heat conduction member and the heat generation component can be previously designed and adjusted according to the heat dissipation requirement.

The main body 11 has an upper surface 111 and a lower surface 112. In this embodiment, the main body 11 is a vapor chamber so that the main body 11 has a first plate body 113 and a second plate body 114. The upper surface 111 is an outer surface of the first plate body 113, while the lower surface 112 is an outer surface of the second plate body 114. The first plate body 113 is mated with the second plate body 114 to together define a chamber 115. The chamber 115 is an airtight chamber having a capillary structure 116 and a working fluid 117. The capillary structure 116 is selected from a group consisting of a sintered powder body, a woven body, a mesh body, a fiber body, a channeled body and any combination thereof.

The lower surface 112 of the main body 11 has at least one connection section 118a and at least one non-connection section 119a in adjacency to the at least one connection section 118a. In this embodiment, the at least one connection section 118a is one connection section 118a corresponding to one heat conduction member 12a. In this embodiment, the at least one non-connection section 119a is one non-connection section 119a around the connection section 118a in adjacency thereto. The connection section 118a of the main body 11 is connected with the heat conduction member 12a to absorb the heat generated by the heat generation component 21 with a height lower than that of the peripheral or adjacent electronic components 23 in operation. The non-connection section 119a of the main body 11 escapes from the electronic components 23 around the heat generation component 21 with a height higher than that of the heat generation component 21. However, the number of the connection section and the number of the non-connection section and the number of the heat conduction member are not limited to one. Some modifications can be made. This will be specifically described hereinafter. The connection section 118a and the non-connection section 119a mean an area of the lower surface 112 of the main body 11, not an extra structure added to the lower surface 112 of the main body 11. The connection section 118a and the non-connection section 119a are shown by the phantom lines in the drawings.

The heat conduction member 12a has a heat absorption face 121 and a heat conduction face 122 respectively positioned on the upper and lower faces of the heat conduction member 12a. The heat conduction face 122 of the heat conduction member 12a is disposed under the connection section 118a of the lower surface 112 of the main body 11 for conducting the heat absorbed by the heat absorption face 121 to the main body 11. The heat absorption face 121 of the heat conduction member 12a is correspondingly attached to the heat generation component 21. In this embodiment, after the heat conduction member 12a is attached to the heat generation component 21, the total height is slightly higher than the height of the electronic components 23 around the heat generation component 21. In a modified embodiment, after the heat conduction member 12a is attached to the heat generation component 21, the total height can be higher than or equal to the height of the electronic components 23 around the heat generation component 21.

In this embodiment, the main body 11 and the heat conduction member 12a of the heat dissipation unit 1 are selectively separate members. The heat conduction face 122 of the heat conduction member 12a is correspondingly connected under the lower surface 112 of the main body 11 for illustration purposes. The main body 11 and the heat conduction member 12a can be made of the same material or different materials. In the case of the same material, the main body 11 and the heat conduction member 12a can be made of the same metal material (such as copper, aluminum, stainless steel or titanium) or the same ceramic material (such as alumina (Al₂O₃), silicon nitride (Si₃N₄) or Zirconia (ZrO₂)). In the case of different materials, the main body 11 and the heat conduction member 12a can be made of different metal materials, different ceramic materials or different metal and ceramic materials.

In the case that the main body 11 and the heat conduction member 12a are made of the same metal material such as copper, the first and second plate bodies 113, 114 of the main body 11 and the heat conduction member 12a are connected by means of diffusion bonding. In a modified embodiment, the main body 11 and the heat conduction member 12a can be made of the same metal material such as gold, silver, copper, iron, aluminum, stainless steel, titanium or alloy material. In this case, the main body 11 and the heat conduction member 12a can be connected by means of a method selected from a group consisting of soldering, brazing, ultrasonic welding, laser welding, adhesion, insertion and inlaying.

In the case that the main body 11 and the heat conduction member 12a are made of the same ceramic material such as alumina (Al₂O₃), the first and second plate bodies 113, 114 of the main body 11 and the heat conduction member 12a are, but not limited to, connected by means of sintering. In a modified embodiment, in the case that the main body 11 and the heat conduction member 12a are made of the same ceramic material such as alumina (Al₂O₃), silicon nitride (Si₃N₄) or Zirconia (ZrO₂), the main body 11 and the heat conduction member 12a can be connected by means of adhesion.

Please refer to FIG. 4. In the case that the main body 11 and the heat conduction member 12a are made of different metal materials, it will be hard to connect the main body 11 and the heat conduction member 12a with each other. For example, in the case that the main body 11 is made of titanium, while the heat conduction member 12a is made of copper, it is hard to connect the titanium material with other metal material by means of welding or fusion. Therefore, in this embodiment, the heat dissipation unit 1 further includes at least one connection medium layer 131. The at least one connection medium layer 131 is correspondingly disposed between the lower surface 112 of the main body 11 and the heat conduction face 122 of the at least one heat conduction member 12a. The lower surface 112 of the main body 11 is connected with the heat conduction face 122 of the at least one heat conduction member 12a via the at least one connection medium layer 131. The heat conduction face 122 of the at least one heat conduction member 12a is correspondingly connected with the at least one connection section 118a of the lower surface 112 of the main body 11. The at least one connection medium layer 131 is correspondingly disposed between the at least one connection section 118a of the main body 11 and the heat conduction face 122 of the at least one heat conduction member 12a.

In this embodiment, the at least one connection medium layer 131 is one connection medium layer 131 corresponding to one connection section 118a and one heat conduction member 12a. In a modified embodiment, the at least one connection medium layer can be more than two connection medium layers corresponding to more than two connection sections and more than two heat conduction members. In other words, the number of the connection medium layers is equal to the number of the corresponding connection sections and the number of the corresponding heat conduction members.

In this embodiment, the connection medium layer 131 is a nickel coating layer. The connection medium layer 131 is formed under the connection section 118a of the lower surface 112 of the main body 11 by means of electroplating. In a modified embodiment, the connection medium layer 131 can be alternatively a tin coating layer or a copper coating layer. In addition, the connection medium layer 131 can be formed under the connection section 118a of the lower surface 112 of the main body 11 by means of evaporation or sputtering.

The heat conduction member 12a is, but not limited to, connected under the connection medium layer 131 formed under the lower surface 112 of the main body 11 by means of diffusion bonding. In a modified embodiment, the main body 11 can be made of a material selected from a group consisting of gold, silver, copper, iron, aluminum, stainless steel and alloy material. The heat conduction member 12a can be made of another material selected from a group consisting of gold, silver, copper, iron, aluminum, stainless steel, titanium and alloy material, which is different from the material of the main body 11. In still a modified embodiment, the main body 11 and the heat conduction member 12a are made of different metal materials (such as gold, silver, copper, iron, aluminum, stainless steel, titanium and alloy material) and the heat conduction member 12a is connected under the connection medium layer 131 formed under the lower surface 112 of the main body 11 by means of a method selected from a group consisting of soldering, brazing, ultrasonic welding and laser welding.

In the case that the main body 11 and the heat conduction member 12a are made of different metal materials and ceramic materials, for example, the main body 11 is made of alumina (Al₂O₃), while the heat conduction member 12a is made of copper material, the heat conduction member 12a is, but not limited to, connected under the connection medium layer 131 formed under the lower surface 112 of the main body 11 by means of diffusion bonding. In a modified embodiment, the main body 11 can be made of silicon nitride (Si₃N₄) or Zirconia (ZrO₂), while the heat conduction member 12a can be made of a material selected from a group consisting of gold, silver, copper, iron, aluminum, stainless steel, titanium and alloy material.

In the case that the main body 11 is made of copper, while the heat conduction member 12a is made of alumina (Al₂O₃), the heat conduction member 12a is connected under the lower surface 112 of the main body 11 by means of direct bonding copper (DBC).

In the above embodiments, the main body 11 and the heat conduction member 12a are separate members. In a modified embodiment, the heat conduction face 122 of the heat conduction member 12a can be alternatively integrally formed under the lower surface 112 of the main body 11.

According to the design of the main body connected with the heat conduction member of the present invention, the non-connection section 119a of the main body 11 can escape from the electronic components 23 around the heat generation component 21 with a height higher than that of the heat generation component 21. Therefore, via the heat conduction member 12a, the connection section 118a of the main body 11 can absorb the heat generated by the heat generation component 21 with a height lower than that of the peripheral or adjacent electronic components 23 in operation and quickly uniformly dissipate the heat outward. Accordingly, the heat of the lower heat generation component 21 can be effectively dissipated. In addition, when dissipating the heat of the heat generation component 21 with a height lower than that of the peripheral or adjacent electronic components 23, it is unnecessary to bend (sink) the main body 11. Therefore, the capillary structure 116 in the chamber 115 will not be damaged to block the vapor passage. In this case, a better heat dissipation effect can be achieved. Furthermore, the connection medium layer is formed under the lower surface of the main body so that the main body 11 and the heat conduction member 12a made of different materials can be more securely connected. For example, the main body 11 can be made of a material with better structural strength, such as stainless steel, titanium or ceramic material, while the heat conduction member 12a can be made of a material with better thermal conductivity, such as copper or aluminum. In this case, the heat dissipation unit 1 of the present invention can have both the advantages of better structural strength and better thermal conductivity.

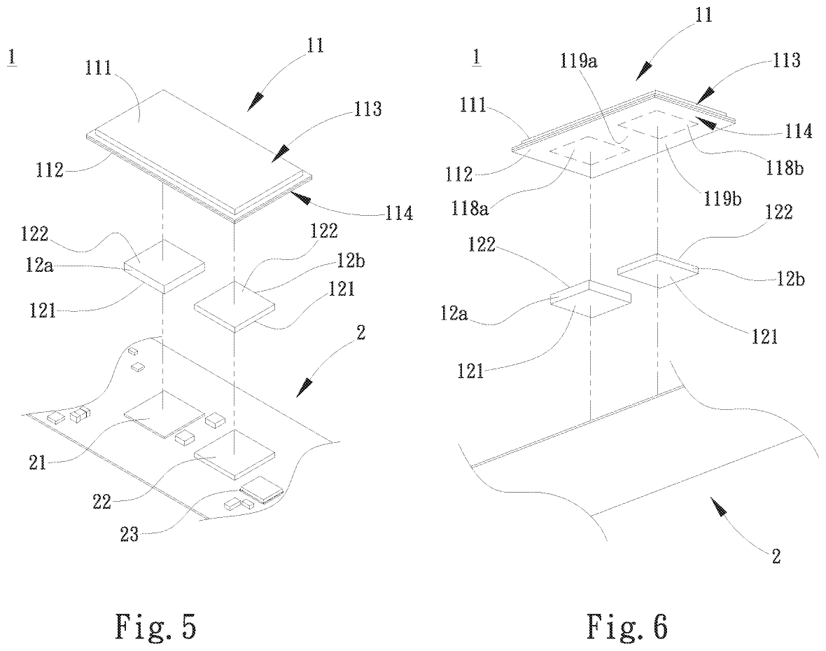

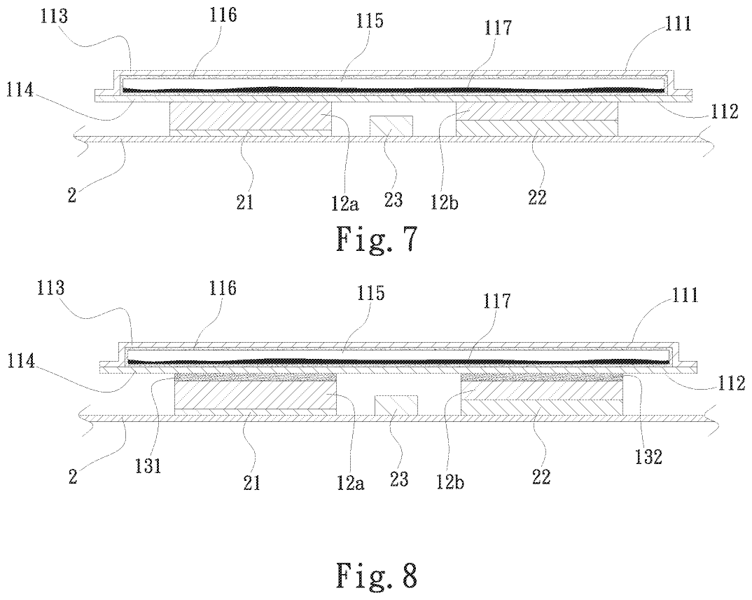

Please now refer to FIGS. 5, 6 and 7. FIG. 5 is a perspective exploded view of a second embodiment of the heat dissipation unit of the present invention. FIG. 6 is a perspective exploded view of the second embodiment of the heat dissipation unit of the present invention, seen from another angle. FIG. 7 is a sectional assembled view of the second embodiment of the heat dissipation unit of the present invention. Also referring to FIGS. 1 to 3, the second embodiment is partially identical to the first embodiment in structure and function and thus will not be redundantly described hereinafter. The second embodiment is different from the first embodiment in that the heat dissipation unit 1 has multiple heat conduction members 12a, 12b. In this embodiment, there are two heat conduction members 12a, 12b with different heights corresponding to two heat generation components 21, 22 with different heights. The number of the heat conduction members and the number of the heat generation components are not limited to two. The numbers and heights of the heat conduction members and the heat generation components can be previously designed and adjusted according to the heat dissipation requirement. The number and height of the heat conduction members are equal to the number and height of the heat generation components. For example, there are three heat conduction members (higher, middle and lower heat conduction members) with different heights corresponding to three heat generation components (higher, middle and lower heat generation components) with different heights, and so on.

The lower surface 112 of the main body 11 has multiple connection sections 118a, 118b and multiple non-connection sections 119a, 119b in adjacency to the connection sections 118a, 118b. In this embodiment, the connection sections 118a, 118b are two connection sections 118a, 118b corresponding to two heat conduction members 12a, 12b. In this embodiment, the non-connection sections 119a, 119b are two non-connection sections 119a, 119b. The first non-connection section 119a is positioned between the first and second connection sections 118a, 118b. The second non-connection section 119b is positioned around the first and second connection sections 118a, 118b in adjacency thereto. In a modified embodiment, alternatively, there can be more than three connection sections corresponding to more than three heat conduction members. In other words, the number of the connection sections is equal to the number of the corresponding heat conduction members and there can be more than three non-connection sections corresponding to more than three connection sections.

The heat conduction faces 122 of the heat conduction members 12a, 12b are respectively correspondingly connected under the connection sections 118a, 118b of the main body 11. That is, the heat conduction face 122 of the first heat conduction member 12a is connected under the first connection section 118a of the main body 11, while the heat conduction face 122 of the second heat conduction member 12b is connected under the second connection section 118b of the main body 11. The heat conduction faces 122 of the heat conduction members 12a, 12b serve to conduct the heat absorbed by the heat absorption faces 121 to the main body 11.

In addition, the heat absorption faces 121 of the two heat conduction members 12a, 12b with different heights are correspondingly attached to two heat generation components 21, 22 with different heights. That is, the height of the first heat generation component 21 is lower than the height of the second heat generation component 22, while the height of the first heat conduction member 12a is higher than the height of the second heat conduction member 12b. Accordingly, the heat absorption face 121 of the first heat conduction member 12a is in contact with and attached to the first heat generation component 21, while the heat absorption face 121 of the second heat conduction member 12b is in contact with and attached to the second heat generation component 22. Accordingly, the heights of the first and second heat conduction members 12a, 12b are designed and adjusted in adaptation to the heights of the first and second heat generation components 21, 22, whereby after the first and second heat conduction members 12a, 12b are attached to the first and second heat generation components 21, 22, the total heights are equal to each other.

For example, after the first heat conduction member 12a is attached to the first heat generation component 21 and the second heat conduction member 12b is attached to the second heat generation component 22, the total height of the first heat conduction member 12a and the first heat generation component 21 is equal to the total height of the second heat conduction member 12b and the second heat generation component 22. Also, after the first and second heat conduction members 12a, 12b are attached to the first and second heat generation components 21, 22, the total height is higher than and/or equal to the height of the electronic components 23 around the heat generation components 21, 22 or in adjacency to the heat generation components 21, 22.

According to the design of the main body connected with the heat conduction members of the present invention, the height of the main body 11 is higher than and/or equal to the height of the electronic components 23 around the heat generation components 21, 22. Via the multiple heat conduction members 12a, 12b with different heights, the main body 11 can absorb the heat generated by multiple heat generation components 21, 22 with different heights in operation and quickly uniformly dissipate the heat outward. Accordingly, the heat of the heat generation components 21, 22 with different heights can be effectively dissipated. In addition, when dissipating the heat of the heat generation components 21, 22 with different heights, it is unnecessary to bend (sink) the main body 11. Therefore, the capillary structure 116 in the chamber 115 will not be damaged to block the vapor passage. In this case, a better heat dissipation effect can be achieved.

Please refer to FIG. 8. In the case that the main body 11 and the heat conduction members 12a, 12b are made of different metal materials or the main body 11 is made of a ceramic material, while the heat conduction members 12a, 12b are made of metal materials, the main body 11 and the heat conduction members 12a, 12b can be connected with each other by means of the aforesaid methods as shown in FIG. 4, which will not be repeatedly described hereinafter.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

1. A heat dissipation unit comprising:
a main body having an upper surface and a lower surface; and
at least one heat conduction member having a heat absorption face and a heat conduction face, the heat conduction face of the heat conduction member being disposed under the lower surface of the main body, the main body and the at least one heat conduction member being separate members;
at least one connection medium layer correspondingly disposed between the lower surface of the main body and the heat conduction face of the at least one heat conduction member, the lower surface of the main body being connected with the heat conduction face of the at least one heat conduction member via the at least one connection medium layer.

2. (canceled)

3. A heat dissipation unit comprising:
a main body having an upper surface and a lower surface; and
at least one heat conduction member having a heat absorption face and a heat conduction face, the heat conduction face of the heat conduction member being disposed under the lower surface of the main body, the heat conduction face of the at least one heat conduction member being integrally formed under the lower surface of the main body.

4. The heat dissipation unit as claimed in claim 1, wherein the main body is selected from a group consisting of a heat conduction base body, a heat sink, a vapor chamber, a heat pipe, a loop-type heat pipe and any combination thereof.

5. The heat dissipation unit as claimed in claim 1, wherein the main body has a first plate body and a second plate body, the upper surface being an outer surface of the first plate body, the lower surface being an outer surface of the second plate body, the first plate body being mated with the second plate body to together define a chamber, the chamber having a capillary structure and a working fluid.

6. The heat dissipation unit as claimed in claim 1, wherein the main body and the at least one heat conduction member are made of the same material or different materials.

7. The heat dissipation unit as claimed in claim 1, wherein the main body and the at least one heat conduction member are made of metal material or ceramic material, the metal material being selected from a group consisting of gold, silver, copper, iron, aluminum, stainless steel, titanium and alloy material, the ceramic material being selected from a group consisting of silicon nitride (Si₃N₄), Zirconia (ZrO₂) and alumina (Al₂O₃).

8. The heat dissipation unit as claimed in claim 1, wherein the main body and the at least one heat conduction member are connected by means of a method selected from a group consisting of soldering, brazing, diffusion bonding, ultrasonic welding, laser welding, adhesion, insertion, inlaying, sintering and direct bonding copper (DBC).

9. The heat dissipation unit as claimed in claim 1, wherein the lower surface of the main body has at least one connection section and at least one non-connection section in adjacency to the at least one connection section, the heat conduction face of the at least one heat conduction member being disposed under the at least one connection section of the lower surface of the main body.

10. The heat dissipation unit as claimed in claim 9, comprising multiple heat conduction members with different heights, the lower surface of the main body having multiple connection sections and multiple non-connection sections in adjacency to the connection sections, the heat conduction faces of the heat conduction members being respectively disposed under the connection sections, the heat absorption faces of the heat conduction members being correspondingly attached to multiple heat generation components with different heights.

11. (canceled)

12. The heat dissipation unit as claimed in claim 1, wherein the lower surface of the main body has at least one connection section and at least one non-connection section in adjacency to the at least one connection section, the heat conduction face of the at least one heat conduction member being disposed under the at least one connection section of the lower surface of the main body, the at least one connection medium layer being correspondingly disposed between the at least one connection section of the main body and the heat conduction face of the at least one heat conduction member.

13. The heat dissipation unit as claimed in claim 1, wherein the at least one connection medium layer is formed under the lower surface of the main body by means of evaporation, sputtering or electroplating.

14. The heat dissipation unit as claimed in claim 1, wherein the at least one connection medium layer is a nickel coating layer, a tin coating layer or a copper coating layer.

15. The heat dissipation unit as claimed in claim 1, wherein the at least one connection medium layer is connected with the at least one heat conduction member by means of a method selected from a group consisting of soldering, brazing, diffusion bonding, ultrasonic welding and laser welding.

16. The heat dissipation unit as claimed in claim 1, comprising multiple heat conduction members with different heights, the lower surface of the main body having multiple connection sections and multiple non-connection sections in adjacency to the connection sections, the heat conduction faces of the heat conduction members being respectively disposed under the connection sections, the multiple connection medium layers being correspondingly disposed between the connection section of the lower surface of the main body and the heat conduction faces of the heat conduction members, the heat absorption faces of the heat conduction members being correspondingly attached to multiple heat generation components with different heights.
